(19) United States
(12) Patent Application Publication
(10) Pub. No.: US 2015/0069432 A1
(43) Pub. Date: Mar. 12, 2015

(54) LIGHT-EMITTING STRUCTURE

(71) Applicants: LITE-ON OPTO TECHNOLOGY (CHANGZHOU) CO., LTD., CHANGZHOU CITY (CN); LITE-ON TECHNOLOGY CORPORATION, TAIPEI CITY (TW)

(72) Inventor: KUO-MING CHIU, NEW TAIPEI CITY (TW)

(21) Appl. No.: 14/541,327

(22) Filed: Nov. 14, 2014

Related U.S. Application Data
(63) Continuation-in-part of application No. 13/531,462, filed on Jun. 22, 2012.

(30) Foreign Application Priority Data
Mar. 24, 2014 (CN) 201410111654.1

(51) Int. Cl. H01L 25/075; H01L 33/64; H01L 33/50

(52) U.S. Cl. CPC H01L 25/0753; H01L 33/504; H01L 33/507; H01L 33/644
USPC 257/89

(57) ABSTRACT

A light-emitting structure includes a substrate and a light-emitting unit. The substrate has a first meander conductive track and a second meander conductive track. Each first chip-mounting area of the first meander conductive track has at least two first chip-mounting lines. Each second chip-mounting area of the second meander conductive track has at least two second chip-mounting lines. The light-emitting unit includes first light-emitting groups and second light-emitting groups. Each first light-emitting group includes at least one or a plurality of first LED chips disposed on the same first chip-mounting line of the corresponding first chip-mounting area, and each second light-emitting group includes at least one or a plurality of second LED chips disposed on the same second chip-mounting line of the corresponding second chip-mounting area. The first and the second chip-mounting areas are arranged alternately, thus the first and the second light-emitting groups are arranged alternately.

### CROSS REFERENCE TO RELATED APPLICATION

This application is a continuation-in-part of U.S. application Ser. No. 13/531,462, filed on 22 Jun. 2012 and entitled “LED PACKAGE STRUCTURE”, now pending, the entire disclosures of which are incorporated herein by reference.

### BACKGROUND OF THE INVENTION

1. Field of the Invention

The present disclosure relates to a light-emitting structure; in particular, to a light emitting structure which provides a color tunable LEDs device by a combination of warm white and cool white multi CSP (Chip Scale Package) LEDs.

2. Description of Related Art

Comparing light-emitting diodes to traditional light sources, the light-emitting diodes (LEDs) is small, saves electricity, has good light emission efficiency, has a long life span, is responsive, and does not produce thermal radiation, mercury or other pollutants. Therefore in recent years, application of LEDs has become more widespread.

### SUMMARY OF THE INVENTION

The object of the present disclosure is to provide a light-emitting structure having warm white and cool white multi CSP (Chip Scale Package) LEDs capable of uniform mixing color.

According to the present disclosure, the light-emitting structure, which has at least two meandering conductive tracks on a substrate and a light-emitting unit having cool white LEDs and warm white LEDs alternately arranged and mounted on thereof. Thus, a predetermined fixed target color temperature, a fine adjustment of color temperature can be achieved.

In order to further the understanding regarding the present disclosure, the following embodiments are provided along with illustrations to facilitate the disclosure of the present disclosure.

### BRIEF DESCRIPTION OF THE DRAWINGS

FIG. 1 shows a top view of a light-emitting structure according to a first embodiment of the present disclosure;

FIG. 2 shows a partial side cross-sectional view of a light-emitting structure using air layer as a thermal resistant structure according to a first embodiment of the present disclosure;

FIG. 3 shows a partial side cross-sectional view of a light-emitting structure using a layer of material having high heat resistance as a thermal resistant structure according to a first embodiment of the present disclosure;

FIG. 4 shows a top view of a plurality of first LED chips and a plurality of second LED chips arranged in an approximately circular region according to a first embodiment of the present disclosure;

FIG. 5 shows a top view of a plurality of first LED chips and a plurality of second LED chips arranged in a circular region according to a first embodiment of the present disclosure;

FIG. 6 shows a schematic diagram of another method for offsetting a first LED chip onto a circular track according to a first embodiment of the present disclosure;

FIG. 7 shows a schematic diagram of first LED chips and second LED chips disposed in vertical paths and in an approximately circular region according to a first embodiment of the present disclosure;

FIG. 8 shows a top view of two independent groups of light-emitting structures according to a first embodiment of the present disclosure;

FIG. 9 shows a top view of two groups of light-emitting structures connected in parallel according to a first embodiment of the present disclosure;

FIG. 10 shows a side cross-sectional view of a light structure according to a second embodiment of the present disclosure;

FIG. 11 shows a side cross-sectional view of a light structure according to a third embodiment of the present disclosure;

FIG. 12 shows a side cross-sectional view of a light structure according to a fourth embodiment of the present disclosure;

FIG. 13 shows a side cross-sectional view of a light structure according to a fifth embodiment of the present disclosure;

FIG. 14 shows a side cross-sectional view of a light structure according to a sixth embodiment of the present disclosure;

FIG. 15 shows a side cross-sectional view of a light structure according to a seventh embodiment of the present disclosure;

FIG. 16 shows a side cross-sectional view of a light structure according to an eighth embodiment of the present disclosure;

FIG. 17 shows a top view including a frame gel body according to a ninth embodiment of the present disclosure;

FIG. 18 shows a top view of a light-emitting structure according to a ninth embodiment of the present disclosure;

FIG. 19 shows a top view including a frame gel body according to a tenth embodiment of the present disclosure; and

FIG. 20 shows a top view of a light-emitting structure according to a tenth embodiment of the present disclosure.

### DETAILED DESCRIPTION OF THE PREFERRED EMBODIMENTS

### First Embodiment

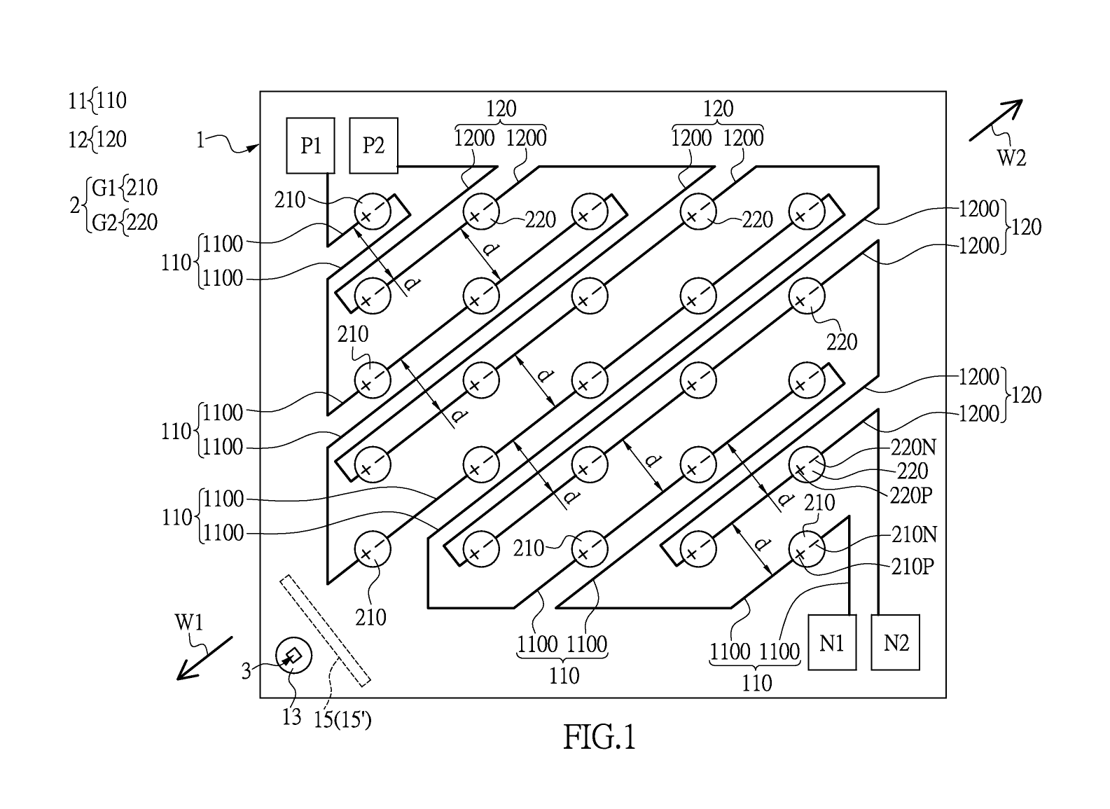

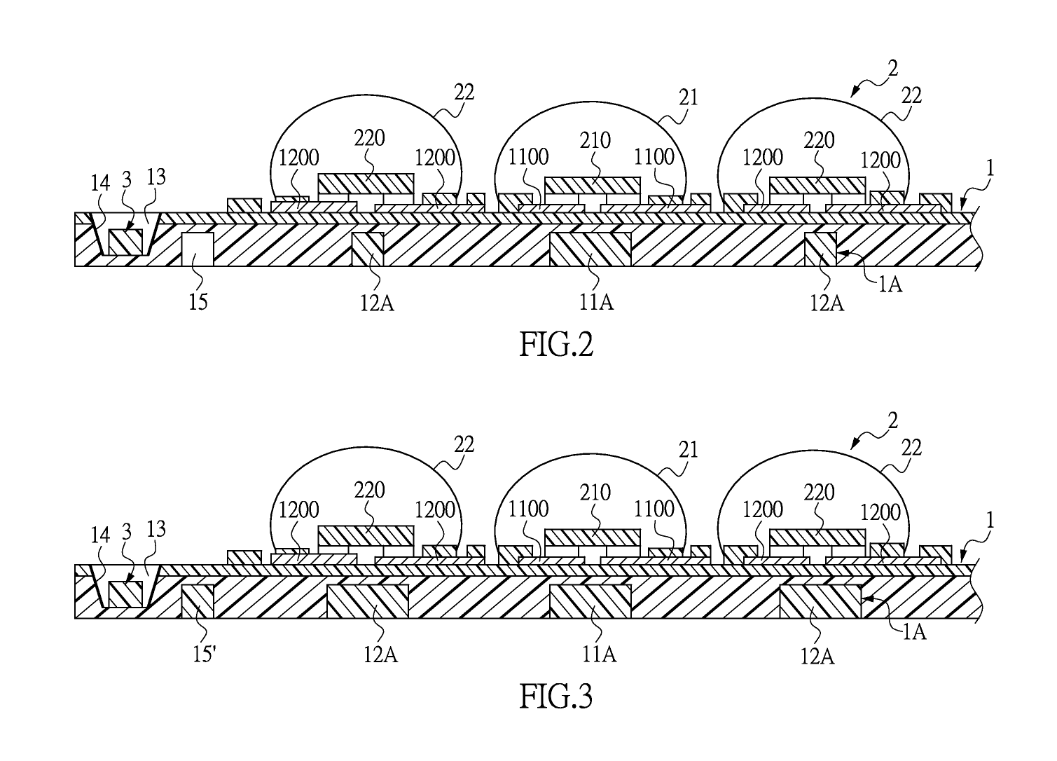

Referring to FIG. 1 and FIG. 2, a first embodiment of the present disclosure provides a light-emitting structure including a substrate 1 and a light-emitting unit 2.

As shown in FIG. 1, the upper surface of the substrate 1 has at least one meandering first conductive track 11 and at least one meandering second conductive track 12. The at least one first conductive track 11 has a plurality of first chip-mounting areas 110. The at least one second conductive track 12 has a plurality of second chip-mounting areas 120. The first chip-mounting areas 110 and the second chip-mounting areas 120 are alternately arranged. Additionally, each of the first chip-mounting areas 110 has at least two first chip-mounting lines 1100 arranged proximal to each other and in series. Each of the second chip-mounting areas 120 has at least two second chip-mounting lines 1200 arranged proximal to each other and in series. For example, as shown in FIG. 1, the meandering shapes of the first conductive track 11 and the second conductive track 12 are similar to an S-shaped serial connection. The meandering first conductive track 11 and the meandering second conductive track 12 are arranged close to each other in the form of interlocking fingers of two hands but without contacting each other, such that the first conductive track 11 and the second conductive track 12 present a line design of alternate arrangement. Additionally, the plurality of first chip-mounting lines 1100 and the plurality of second chip-mounting lines 1200 can be parallel to each other, but the present disclosure is not limited thereto.

Specifically, as shown in FIG. 1, two opposite ends of the first conductive track 11 are respectively connected to a first positive bonding pad P1 and a first negative bonding pad N1, and two opposite ends of the second conductive track 12 are respectively connected to a second positive bonding pad P2 and a second negative bonding pad N2. For example, the first positive bonding pad P1 and the second positive bonding pad P2 can be arranged proximal to each other at a corner of the substrate 1, and the first negative bonding pad N1 and the second negative bonding pad N2 are arranged proximal to each other at the opposite corner on the substrate 1. The width of the first conductive track 11 extending from the first positive bonding pad P1 to the first negative bonding pad N1, and the width of the second conductive track 12 extending from the second positive bonding bad P2 to the second negative bonding pad N2 gradually increase and decrease along a diagonal line on the substrate 1, thereby increasing the area of distribution of the first conductive track 11 and the second conductive track 12.

Moreover, referring to FIG. 1 and FIG. 2, the light-emitting unit 2 includes a plurality of first light-emitting groups G1 and a plurality of second light-emitting groups G2. The color temperature of the first light-emitting groups G1 is smaller than the color temperature of the second light-emitting groups G2. Each of the first light-emitting groups G1 includes one or more first LED chips 210. Each of the second light-emitting groups G2 includes one or more second LED chips 220. Specifically, as shown in FIG. 1, each of the positive bonding pads 210P of the first LED chips 210 and each of the positive bonding pads 220P of the second LED chips 220 are all directed toward a first predetermined direction W1 relative to the substrate 1. Each of the negative bonding pads 210N of the first LED chips 210 and each of the negative bonding pads 220N of the second LEC chips 220 are all directed toward a second predetermined direction W2 relative to the substrate 1. The first predetermined direction W1 and the second predetermined direction W2 are opposite directions. By this configuration, regarding each individual chip, the orientation relative to the substrate 1 of the positive and negative bonding pads (210P, 210N) of each of the first LED chips 210 is the same as the orientation relative to the substrate 1 of the positive and negative bonding pads (220P, 220N) of each of the second LED chips 220. During the process of disposing chips, the positive terminals and the negative terminals of the first LED chips 210 and the second LED chips 220 do not need to be turned, increasing production efficiency.

Specifically, in order to achieve the design of the above-mentioned “the orientation relative to the substrate 1 of the positive and negative bonding pads (210P, 210N) of each of the first LED chips 210 is the same as the orientation relative to the substrate 1 of the positive and negative bonding pads (220P, 220N) of each of the second LED chips 220,” the one or more first LED chips 210 of each of the first light-emitting groups G1 can only be placed on one of the first chip-mounting lines 1100 of the respective first chip-mounting area 110, and the one or more second LED chips 220 of each of the second light-emitting groups G2 can only be placed on one of the second chip-mounting lines 1200 of the respective second chip-mounting area 120. For example, as shown in FIG. 1, in order to orient the positive bonding pad 210P of each of the first LED chips 210 toward the first predetermined direction W1, the one or more first LED chips 210 of each of the first light-emitting groups G1 can only be placed on the first chip-mounting line 1100 closer to the first positive bonding pad P1 of two neighboring first chip-mounting lines 1100. Likewise, in order to orient the positive bonding pad 220P of each of the second LED chips 220 toward the first predetermined direction W1, the one or more second LED chips 220 of each of the second light-emitting groups G2 can only be placed on the second chip-mounting line 120 further from the second positive bonding pad P2 of two neighboring second chip-mounting lines 1200.

As shown in FIG. 1, in order to achieve the design of “the positive terminals and the negative terminals of the first LED chips 210 and the second LED chips 220 do not need to be turned,” the one or more first LED chips 210 of each of the first light-emitting groups G1 can be disposed on the same corresponding first chip-mounting line 1100 of the first chip-mounting area 110, to form first LED chips 210 which do not need to be turned to realign the positive terminal and the negative terminal during chip disposing process, and the one or more second LED chips 220 of each of the second light-emitting groups G2 can be disposed on the same corresponding second chip-mounting line 1200 of the second chip-mounting area 120, to form second LED chips 220 which do not need to be turned to realign the positive terminal and the negative terminal during chip disposing process. Additionally, since the first chip-mounting areas 110 and the second chip-mounting areas 120 are alternately arranged, the first light-emitting groups G1 and the second light-emitting groups G2 are also alternately arranged and capable increasing light mixing effect of light-emitting groups of different color temperatures.

For example, as shown in FIG. 1, the first LED chips 210 and the second LED chips 220 can be alternately arranged as an array, so that the first LED chips 210 and the second LED chips 220 present an alternating arrangement from a vertical or a horizontal perspective. Additionally, the first chip-mounting lines 1100 having first LED chips 210 disposed thereon and the second chip-mounting lines 1200 having second LED chips 220 disposed thereon can be parallel to each other and have the same interval distance D therebetween, such that any neighboring first light-emitting group G1 and second light-emitting group G2 can be parallel to each other and be separate by an interval distance D. Therefore, the light source of different color temperatures produced by the plurality of first light-emitting groups G1 and the plurality of second light-emitting groups G2 of the light-emitting unit 2 can be preferably mixed. For example, the first light-emitting groups G1 can be LED units providing a first color temperature, and the second light-emitting groups G2 can be LED units providing a second color temperature. The two sets of LED units producing two different color temperatures can be LED chips of wavelengths in similar ranges configured with two sets of different fluorescent gels, wherein the first color temperature is a relatively low color temperature corresponding to warm white, red, yellow or similar colors, and the second color temperature is a relatively high color temperature corresponding to cold white, blue, green or similar colors.

Specifically, as shown in FIG. 1, since the first conductive track 11 and the second conductive track 12 extend along a diagonal line of the substrate 1 such that the horizontal width of the meandering tracks present changes of “gradual increase and decrease,” so that the quantities of the first LED chips 210 of the first light-emitting groups G1 and the quantities of the second LED chips 220 of the second light-emitting groups G2 sequentially decrease from the middle of the light-emitting unit 2 toward two opposite sides of the light-emitting unit 2, or sequentially increase from two opposite sides of the light-emitting unit 2 toward the middle of the light-emitting unit 2.

For example, as shown in FIG. 1, the quantities of the first LED chips 210 and the quantities of the second LED chips 220 sequentially increase from two opposite corners toward the middle according to the respective formulas 2n−1 and 2n, wherein n is the sequence number of the first light-emitting groups G1 and the second light-emitting groups G2 starting from 1. Therefore, the quantities of the first LED chips 210 increase from the two corners to the middle of the light-emitting unit 2 according to the sequence (2×1−1=1, 2×2−1=3, 2×3−1=5), and the quantities of the second LED chips 220 increase from the two corners to the middle of the light-emitting unit 2 according to the sequence (2×1=2, 2×2=4). By this configuration, the quantities of first LED chips 210 of two neighboring first light-emitting groups G1 differs by two, the quantities of second LED chips 220 of two neighboring second light-emitting groups G2 differs by two, and the quantities of LED chips (210, 220) of a first light-emitting group G1 and a neighboring second light-emitting group G2 differ by 1.

Additionally, as show in FIG. 1 to FIG. 3, the upper surface of the substrate 1 has an accommodating groove 13 for accommodating an electronic component 3. The inner surface of the accommodating groove 13 has a light-absorbing coating 14, and the interior of the substrate 1 has a thermal resistant structure disposed between the electronic component 3 and the light-emitting unit 2. For example, the substrate 1 is a multi-layered ceramic plate which can be formed by Al₂O₃, an adhesive sheet, FR4, a metal layer and a shielding layer, or by AlN, a metal layer and a silicone layer. Light-emitting chips and a gel frame surrounding the light-emitting chips can be disposed on the above, and fluorescent gel can cover the light-emitting chips to form the light-emitting unit 2. Moreover, the electronic component 3 can be an optical sensor, and the light-absorbing coating 14 can be a black coating for reducing reflection, increasing the sensing effect of the optical sensor. Additionally, the thermal resistant structure can be an air layer 15 (as shown in FIG. 2) or a high thermal resistance material 15′ whose thermal resistance is higher than that of the substrate 1 (as shown in FIG. 3), limiting the heat produced by the light-emitting unit 2 from being transmitted to the electronic component 3.

Additionally, regarding the positioning of the electronic component 3 and the thermal resistant structure, for example as shown in FIG. 1, when the electronic component 3 is disposed proximal to a corner of the substrate 1, the thermal resistant structure (15, 15′) can be slantedly disposed between the light-emitting unit 2 and the electronic component 3. According to another possible positioning, when the electronic component 3 is disposed proximal to a transverse (horizontal) edge of the substrate 1, the thermal resistant structure can be vertically (or levelly) disposed between the light-emitting unit 2 and the electronic component 3. Specifically, the thermal resistant structure on the substrate 1 and the subsequent thermal conducting unit can be formed at the same time. In other words, a plurality of indentations or through holes is formed on the back of the substrate 1 at predetermined positions corresponding to the positions of the thermal resistant structure and the thermal conducting unit. The depths of indentations are the same. Then, the indentations or through holes of the thermal resistant structure can be unfilled (and air) or filled with material having high thermal resistance. The indentations or through holes of the thermal conducting unit can be filled with similar or different materials having high thermal conductivity. In other words, the thermal conductivities k1, k2 and k3 of respectively the substrate, the thermal resistant structure and the thermal conducting unit satisfy the relationship of k3>k1>k2. The present embodiment takes the strength of the substrate into consideration and employs a design of indentations.

Specifically, as shown in FIG. 2 and FIG. 3, the substrate 1 further includes a thermal conducting unit 1A embedded in the substrate 1, and the thermal conducting unit 1A includes a plurality of first heat dissipating structures 11A disposed under the plurality of first LED chips 210 and a plurality of second heat dissipating structures 12A disposed under the plurality of second LED chips 220. For example, the first LED chips 210 and the second LED chips 220 become a first LED unit 21 and a second LED unit 22 after packaging (for example using similar or different fluorescent gel for packaging). When the color temperature produced by the first LED unit 21 is lower than the color temperature produced by the second LED unit 22, the first heat dissipating structures 11a and the second heat dissipating structures 12A can use the following design, for balancing the heat dissipation of the first LED unit 21 and the second LED unit 22. Firstly, in the first type, when the first heat dissipating structures 11A and the second heat dissipating structures 12A use materials having similar heat dissipating ability, the overall dimensions (or volume) of the first heat dissipating structures 11A is greater than the overall dimensions (or volume) of the second heat dissipating structures 12A. Additionally, in the second type, when the dimensions of the first heat dissipating structures 11a and the second heat dissipating structures 12A are similar, the heat dissipating ability of the material used by the first heat dissipating structures 11A is greater than the heat dissipating ability of the material used by the second heat dissipating structures 12A. However, the present disclosure is not limited thereto. Additionally, the first LED unit 21 and the second LED unit 22 of different color temperatures results in different contact face temperatures. Therefore, the heat transfer rate Q1 of the first heat dissipating structures 11A and the heat transfer rate Q2 of the second heat dissipating structures 12A can have a ratio Q1:Q2=1:0.86-0.95. Under this preferable ratio, the present embodiment can reduce the difference between the contact face temperatures of the first LED unit 21 and the second Led unit 22. If the light emitted by the first LED unit 21 is warm color temperature 2700K, and the light emitted by the second LED unit 22 is cold color temperature 5700K, for example, then the preferred ratio of heat transfer rate Q1 of the first heat dissipating structures 11A to the heat transfer rate Q2 of the second heat dissipating structures 12A is 1:0.92.

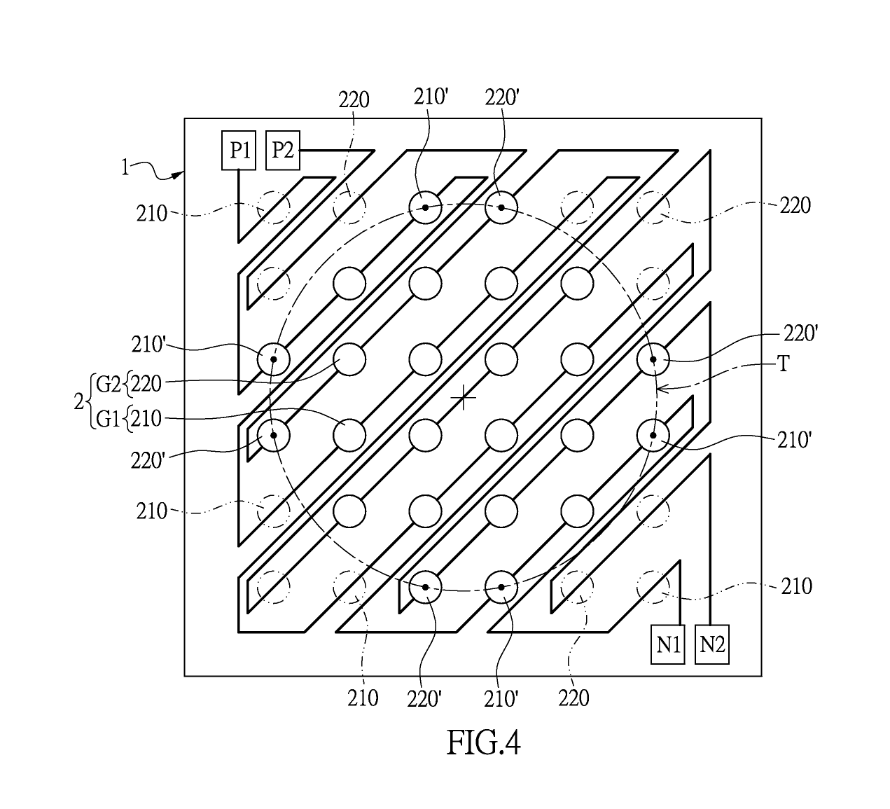

Referring to FIG. 4, taking the 6×6 array of LED chips (210, 220) for example, the total quantity of second Led chips 210 is equal to the total quantity of the second LED chips 220. When the LED chips proximal to the four corners of the substrate 1 are removed (as shown by dotted lines labeled as 210, 220 in FIG. 4), the first LED chips 210 and the second LED chips 220 present an arrangement distribution which is “approximately circular.” Specifically, 4 of the first LED chips 210 are positioned at the outer periphery (labeled as 210′), and 4 of the second LED chips 220 are positioned at the outer periphery (labeled as 220′). Whether using the 4 first LED chips 210′ at the outer periphery or the 4 second LED chips 220′ at the outer periphery as basis (shown as black dots in FIG. 4), a circular path T can be drawn as shown in FIG. 4. In a preferred design, the circular track T drawn by using the 4 first LED chips 210′ at the outer periphery as basis and the circular track T drawn by using the 4 second LED chips 220′ at the outer periphery as basis substantially overlap or completely overlap to form a single circular track T.

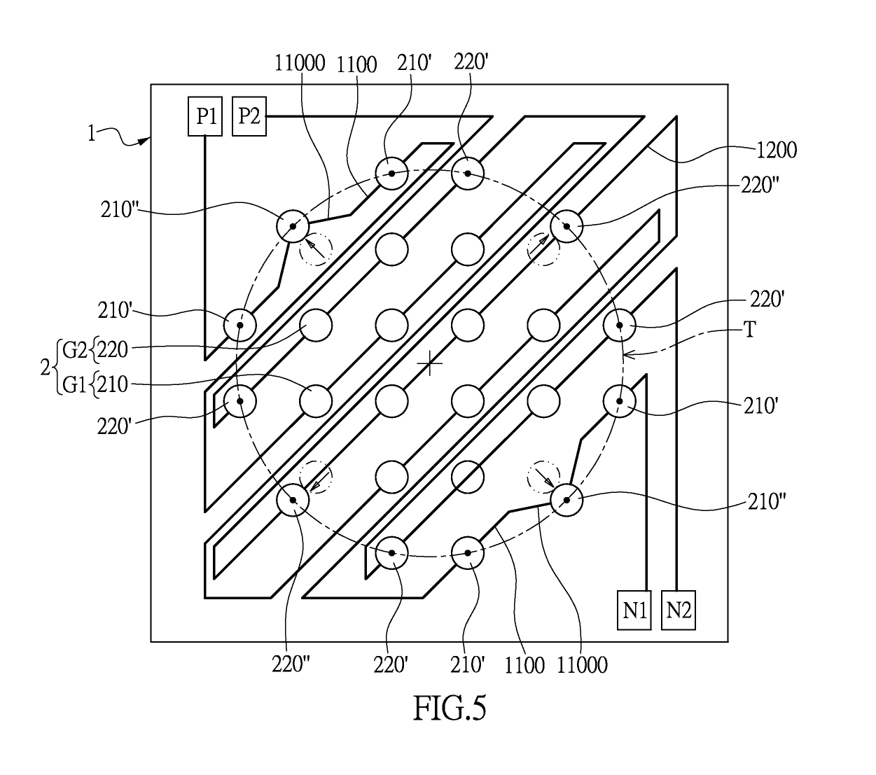

Referring to FIG. 5, in order for the first LED chips (labelled as 210″) proximal to the circular track T to fall exactly on the circular track T, the present disclosure provides a method: when laying the first chip-mounting lines 1100, deviating lines 11000 on the first chip-mounting lines 1100 are designed to directly pass the circular track T. Therefore, when the first LED chips 210″ are offset from the original positions in the direction indicated by arrows shown in FIG. 5 onto the intersections between the deviating lines 11000 and the circular track T, the first LED chips 210″ fall directly on the circular track T. Moreover, in order for the second LED chips (labelled as 220″) proximal to the circular track T to fall exactly on the circular track T, the second chip-mounting line 1200 does not need to be modified, the outer second LED chips 220″ only need to be offset along the second chip-mounting line 1200 in the direction indicated by arrows shown in FIG. 5, and the second LED chips 220″ will fall directly on the circular track T. By this configuration, the first LED chips 210″ and the second LED chips 220″ proximal to the circular track T can be offset to fall directly on the circular track T, so the first LED chips 210 and the second LED chips 220 can present an arrangement distribution which is “approximately circular.”

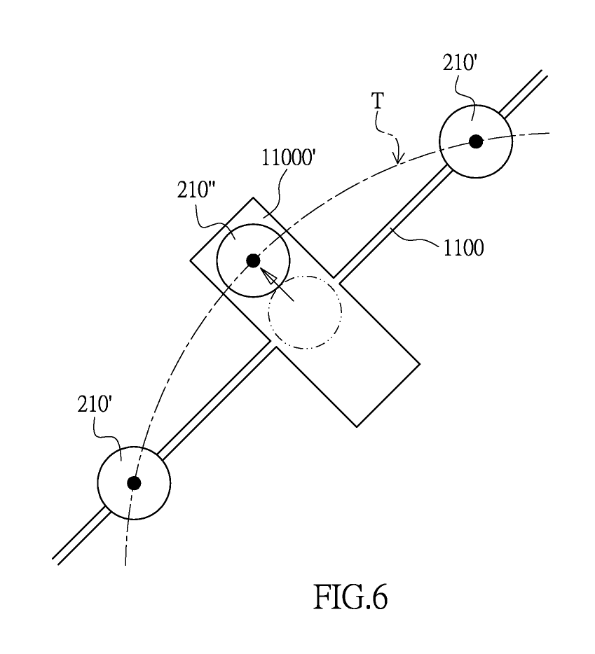

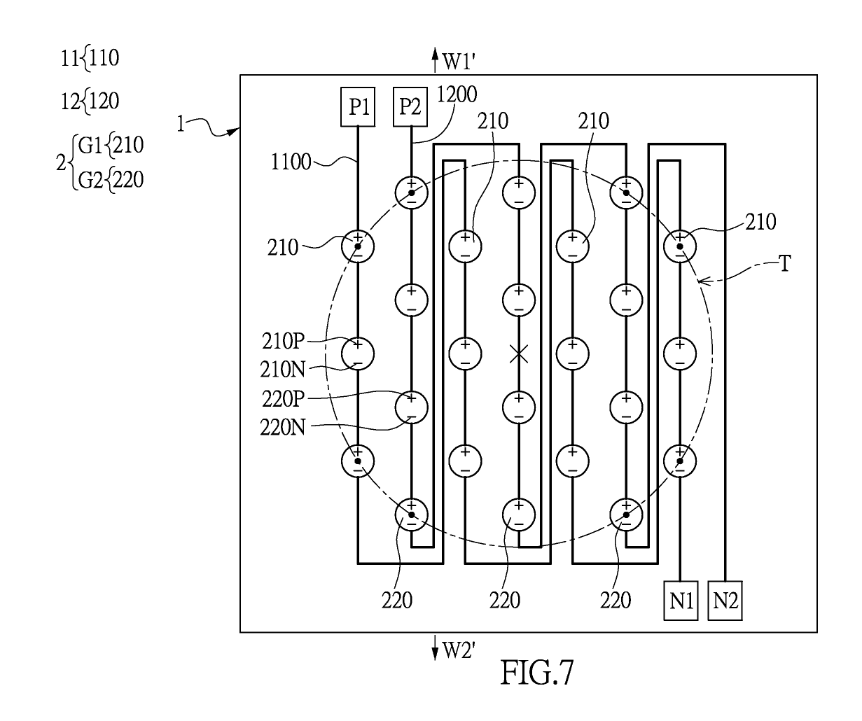

Referring to FIG. 6, in order for the first LED chips (labelled as 210″) proximal to the circular track T to fall exactly on the circular track T, the present disclosure provides another method: when laying the first chip-mounting lines 1100, width-extension segments 11000′ reaching the circular track T are designed on the first chip-mounting line 110, so that the first LED chips 210″ proximal to the circular track T can be directly offset on the width-extension segments 11000′ without modifying the original path of the first chip-mounting lines 1100. Therefore, when the first LED chips 210″ are offset from the original positions in the direction indicated by arrows shown in FIG. 6 onto the circular track T, the first LED chips 210″ fall directly on the circular track T.

As shown in FIG. 7, the first chip-mounting lines 1100 and the second chip-mounting lines 1200 can be modified from the “slanted design” of FIG. 4 to a “vertical design.” This vertical design also allows the first LED chips 210 and the second LED chips 220 to present an arrangement distribution which is “approximately circular.” Of course, through the design of offsetting LED chips as disclosed in FIG. 5 or FIG. 6, the first LED chips 210 and the second LED chips 220 can likewise be made to present an arrangement distribution which is “circular.”

In other words, when presenting a “circular” arrangement distribution, the total quantity of the first LED chips 210 and the total quantity of the second LED chips 220 are equal. The quantities of LED chips (210, 220) of a first light-emitting group G1 and a neighboring second light-emitting group G2 differ by 1. Therefore when the quantity of the first LED chips 210 of each of the first light-emitting groups G1 is N, the quantity of the second LED chips 220 of each of the second light-emitting groups G2 is N+1, the quantity of the first light-emitting groups G1 is N+1, and the quantity of the second light-emitting groups G2 is N, so the total quantity of each type of LED chip is N*(N+1).

Additionally, the color temperature produced by the first LED unit 21 is lower than the color temperature produced by the second LED unit 22, and the heat produced by the first LED unit 21 is greater than the heat produced by the second LED unit 22. So in consideration of overall ability to dissipate heat, the first light-emitting groups G1 of warm color temperature can be distributed at the periphery of the substrate (two sides being first light-emitting groups G1) to prevent heat from gathering and leading to decline in light-emitting efficiency. Therefore, as shown in FIG. 7, the color temperatures of the light-emitting groups from the left to right are respectively cold, warm, cold, warm, cold, warm, cold, warm, cold, and the quantities of LED chips are respectively 3, 4, 3, 4, 3, 4 and 3.

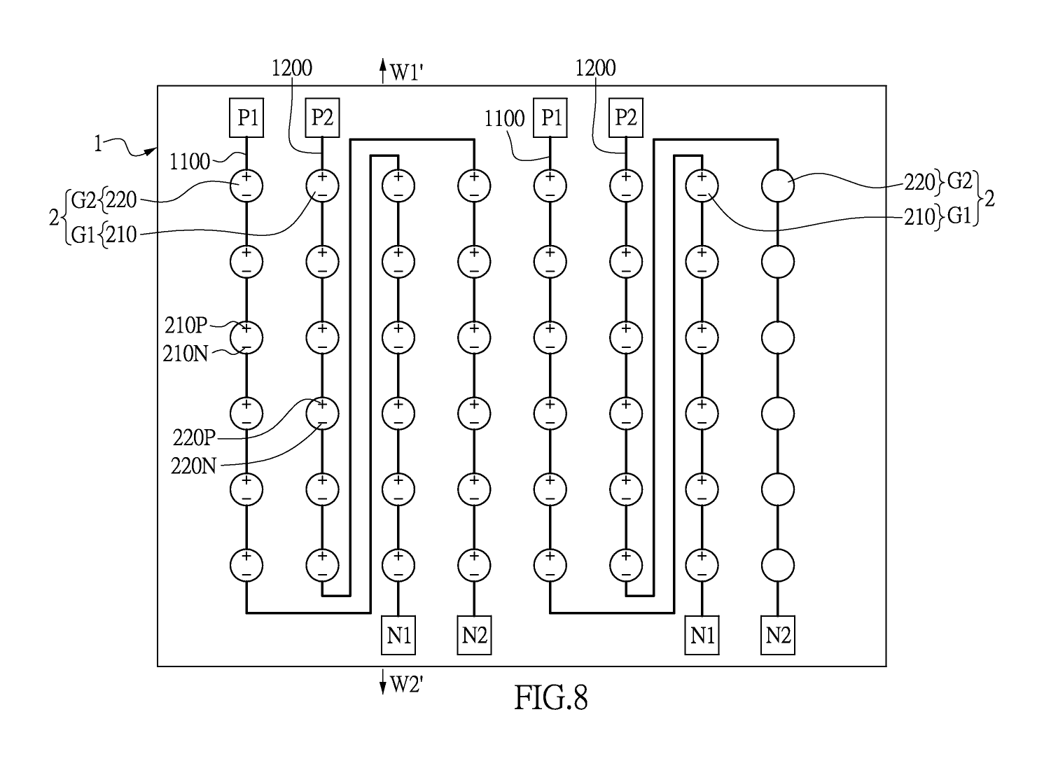

Referring to FIG. 8, under the condition that the present disclosure uses a common substrate 1, two or more independent light-emitting structures can be arranged, and each of the light-emitting structures has an independent first and second positive bonding pads (P1, P2) and first and second negative bonding pads (N1, N2). Through the arrangement of two or more independent light-emitting structures, the first LED chips 210 and the second Led chips 220 not only can present an “array” arrangement distribution as shown in FIG. 7, but also through a design shown in FIG. 4 present an “approximately circular” arrangement distribution. Of course, a design of FIG. 5 of FIG. 6 can be used to present a “circular” arrangement distribution.

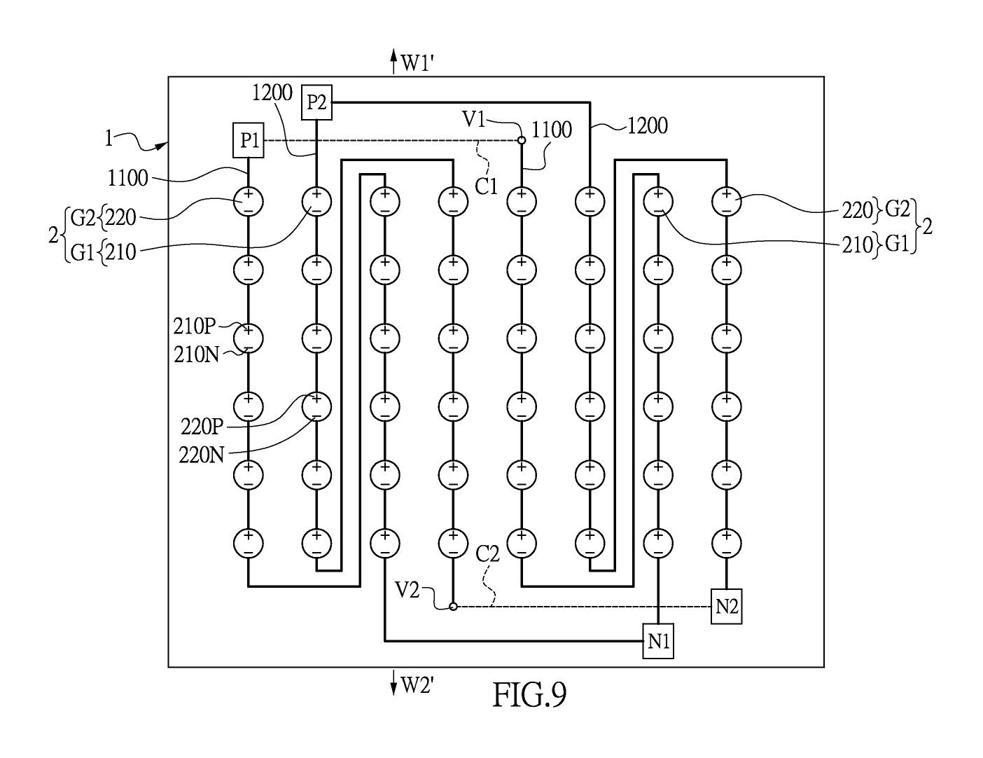

It is worth noting that after the independent light-emitting structures disclosed in FIG. 9 are connected in parallel, the light-emitting structures can commonly use the same first and second positive bonding pads (P1, P2) and the same first and second negative bonding pads (N1, N2). For example, as shown in FIG. 9, assume that the left side and the right side of FIG. 9 are respectively the first and second light-emitting structures, and the first chip-mounting lines 1100 of the first and second light-emitting structures can share the same first positive bonding pad P1 and the same negative bonding pad N1. The first chip-mounting lines 1100 of the first light-emitting structure are directly connected on the upper surface of the substrate 1 to the first positive bonding pad P1. The first chip-mounting lines 1100 of the second light-emitting structure are connected to the first positive bonding pad P1 by passing through a first via hole V1 and in configuration with a first backside circuit C1 on the backside of the substrate 1. The first chip-mounting lines 1100 of the first and second light-emitting structures are directly connected on the upper surface of the substrate 1 to the first negative bonding pad N1. Additionally, the second chip-mounting lines 1200 of the first and second light-emitting structures are directly connected on the upper surface of the substrate 1 to the second positive bonding pad P2. The second chip-mounting lines 1200 of the first light-emitting structure are connected to the second negative bonding pad N2 by passing through a second via hole V2 and in configuration with a second backside circuit C2 on the backside of the substrate 1. The second chip-mounting lines 1200 of the second light-emitting structure are directly connected on the upper surface of the substrate 1 to the second negative bonding pad N2. In other words, one end of the first conductive track 11 and one end of the second conductive track 12 of the first light-emitting structure are respectively connected to the first positive bonding pad P1 and the second positive bonding pad P2, and one end of the first conductive track 11 and one end of the second conductive track 12 of the second light-emitting structure are respectively connected to the first negative bonding pad N1 and the second negative bonding pad N2. The other end of the first conductive track 11 of the second light-emitting structure sequentially through the first via hole and the first backside circuit C1 is indirectly connected to the first positive bonding pad P1, and the other end of the second conductive track 12 of the second light-emitting structure is directly connected to the second positive bonding pad P2. The other end of the first conductive track 11 of the first light-emitting structure is connected to the first negative bonding pad N1, and the other end of the second conductive track 12 of the first light-emitting structure sequentially through the second via hole and the second backside circuit C2 is indirectly connected to the second negative bonding pad N2.

Additionally, regardless of whether the first chip-mounting lines 1100 and the second chip-mounting lines 1200 are “slanted designs” or “vertical designs,” the first chip-mounting lines 1100 and the second chip-mounting lines 1200 are preferably parallel. The positive first LED chips 210 and the second LED chips 220 do not need to turn the positive and negative terminals during chip disposing on the same row. In other words, the positive bonding pad 210P of each of the first LED chips 210 and the positive bonding pad 220P of each of the second LED chips 220 face toward the same first predetermined direction Wr, and the negative bonding pad 210N of each of the first LED chips 210 and the negative bonding pad 220N of each of the second LED chips 220 face toward the same second predetermined direction W2′.

### Second Embodiment

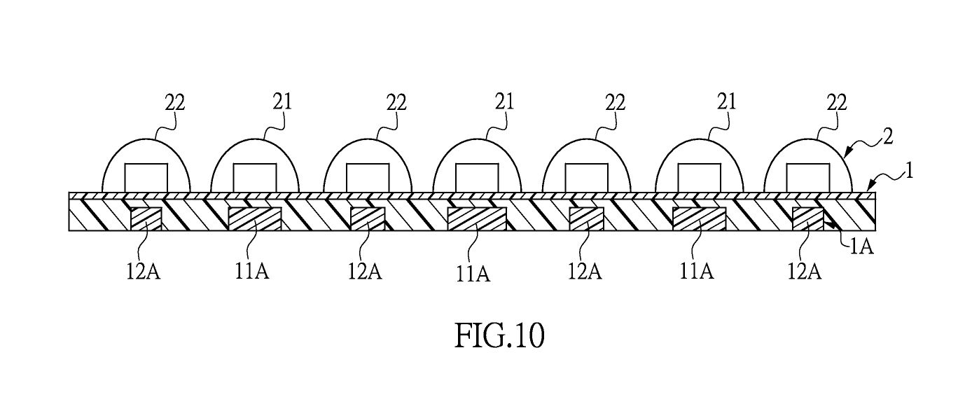

Referring to FIG. 10, the second embodiment of the present disclosure provides a light-emitting structure. From comparison of FIG. 10 to FIG. 2 (or FIG. 3), it can be seen that the greatest difference between the first and second embodiments of the present disclosure lies in that: in the second embodiment, the sizes of the first heat dissipating structures 11A and the second heat dissipating structures 12A gradually decreases from the center of the substrate 1 toward the periphery of the same. By this configuration, the difference between the contact face temperatures of the “first and second LED units (21, 22) at the central region of the substrate 1” and the “first and second LED units (21, 22) at the peripheral region (the region surrounding the central region) of the substrate 1.” Specifically, looking from the center of the substrate 1 toward the periphery, the dimensions of the first heat dissipating structures 11A sequentially decrease by 10% from the center to the periphery (namely the dimensions of two neighboring first heat dissipating structures 11A differ by 10%), and the dimensions of the second heat dissipating structures 12A sequentially decrease by 10% from the center to the periphery (namely the dimensions of two neighboring second heat dissipating structures 12A differ by 10%). Additionally, the heat dissipating ability of a second heat dissipating structure 12A is roughly 0.86-0.95 times that of a neighboring first heat dissipating structure 11A.

### Third Embodiment

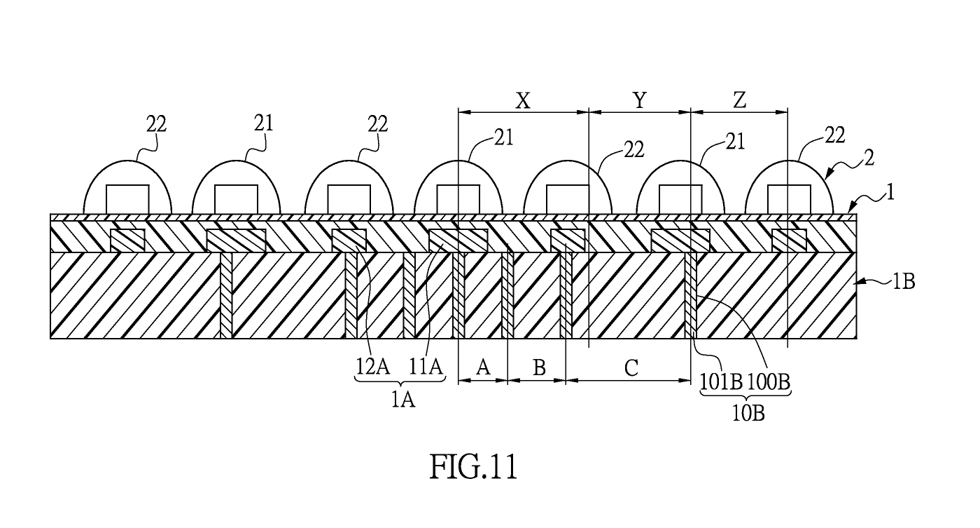

Referring to FIG. 11, the third embodiment of the present disclosure provides a light-emitting structure. From comparison of FIG. 11 to FIG. 2 (or FIG. 3), it can be seen that the greatest difference between the third and first embodiment of the present disclosure lies in that: in the third embodiment, the bottom of the substrate 1 further includes a thermal spreading unit 1B contacting the thermal conducting unit 1A, wherein the interior of the thermal spreading unit 1B includes a plurality of heat dissipating channels 10B which have similar dimensions and are separate, and the gap distances (A, B, C) between two neighboring heat dissipating channels 10B increase from the center of the thermal spreading unit 1B toward the periphery of the same. By this configuration, the heat dissipating channels 10B are sequentially arranged in the direction of “from the center to the periphery of the thermal spreading unit 1B” or “from the periphery to the center of the thermal spreading unit 1B,” to form an incremental thermal conduction structure. Typically, temperature closer to the center is higher. Marking boundaries at every difference of five degrees Kelvin, three heat dissipating regions are defined as shown in FIG. 11 presenting a side cross-sectional view of the light-emitting structure. The three heat dissipating regions (X, Y, Z) progressively cover less horizontal distance from the heat dissipating region X to the heat dissipating region Z. For example, the ratio of the distances of the three heat dissipating regions can be X:Y:Z=5:4:3. When the dimensions of the heat dissipating channels 10B are similar, the gap distances (A, B, C) between two neighboring heat dissipating channels 10B increases from the center to the periphery of the thermal spreading unit 1B (e.g. A:B:C=3:4:5). Therefore the temperature difference between the “first and second LED units (21, 22) at the central region of the thermal spreading unit 1B” and the “first and second LED units (21, 22) at the peripheral region (the region surrounding the central region) of the thermal spreading unit 1B” can be reduced.

Additionally, each of the heat dissipating channels 10B can be a solid heat conducting column formed by a through hole 100 and a heat conducting material 101B (e.g. metal material having high thermal conductivity) completely filling the through hole 100B. The heat dissipating channels 10B can completely pass through the thermal spreading unit 1B. However the present disclosure is not limited thereto. For example, the heat conducting material 101B does not need to completely fill the corresponding through holes 100B, and the heat dissipating channels 10B do not need to completely pass through the thermal spreading unit 1B.

### Fourth Embodiment

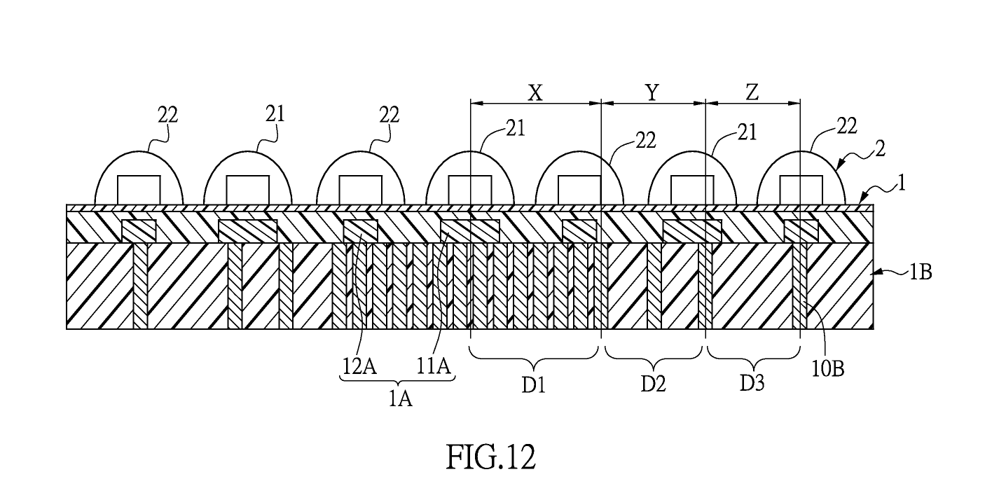

Referring to FIG. 12, the fourth embodiment of the present disclosure provides a light-emitting structure. From comparing FIG. 12 to FIG. 11, it can be seen that the greatest difference between the fourth and third embodiment of the present disclosure lies in that: in the fourth embodiment, the, the volumetric density (D1, D2, D3) of the heat dissipating channels 10B occupying the thermal spreading unit 1B decreases from the center to the periphery of the thermal spreading unit 1B.

For example, marking boundaries at every difference of five degrees Kelvin, three heat dissipating regions are defined as shown in FIG. 12 presenting a side cross-sectional view of the light-emitting structure. The three heat dissipating regions (X, Y, Z) progressively cover less horizontal distance from the heat dissipating region X to the heat dissipating region Z. For example, the ratio of the distances of the three heat dissipating regions can be X:Y:Z=5:4:3. When the dimensions of the heat dissipating channels 10B are similar, the volumetric densities (D1, D2, D3) of heat dissipating channels 10B occupying the thermal spreading unit 1B decreases from the heat dissipating region X to the heat dissipating region Z (e.g. D1:D2:D3=6.5:2:1). Therefore the temperature difference between the “first and second LED units (21, 22) at the central region of the thermal spreading unit 1B” and the “first and second LED units (21, 22) at the peripheral region of the thermal spreading unit 1B” can be reduced.

### Fifth Embodiment

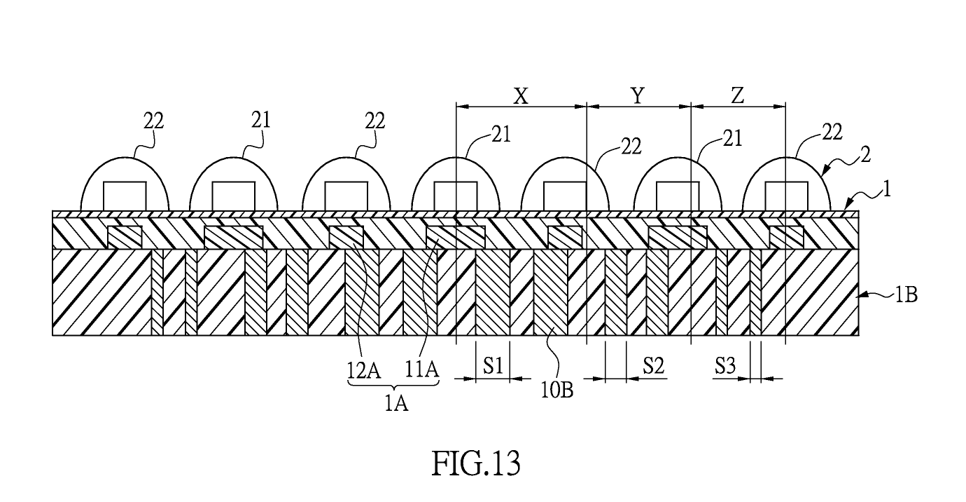

Referring to FIG. 13, the fifth embodiment of the present disclosure provides a light-emitting structure. From comparison of FIG. 13 to FIG. 11, it can be seen that the greatest difference between the fifth and third embodiment of the present disclosure lies in that: in the fifth embodiment, the interior of the thermal spreading unit 1B includes a plurality of separate heat dissipating channels 10B, and the dimensions (S1, S2, S3) of the thermal dissipating channels 10B decrease from the center to the periphery of the thermal spreading unit 1B.

For example, marking boundaries at every difference of five degrees Kelvin, three heat dissipating regions are defined as shown in FIG. 13 presenting a side cross-sectional view of the light-emitting structure. The three heat dissipating regions (X, Y, Z) progressively cover less horizontal distance from the heat dissipating region X to the heat dissipating region Z. For example, the ratio of the distances of the three heat dissipating regions can be X:Y:Z=5:4:3. The fifth embodiment uses heat dissipating channels 10B of different dimensions, and the dimensions (S1, S2, S3) of the heat dissipating channels 10B decrease from the heat dissipating region X to the heat dissipating region Y (e.g. S1:S2:S3=5:4:3). Therefore, the heat dissipating effect of the “first and second LED units (21, 22) at the central region of the thermal spreading unit 1B” is better than the heat dissipating effect of the “first and second LED units (21, 22) at the peripheral region of the thermal spreading unit 1B,” thereby reducing the temperature difference between the “first and second LED units (21, 22) at the central region of the thermal spreading unit 1B” and the “first and second LED units (21, 22) at the peripheral region of the thermal spreading unit 1B.”

### Sixth Embodiment

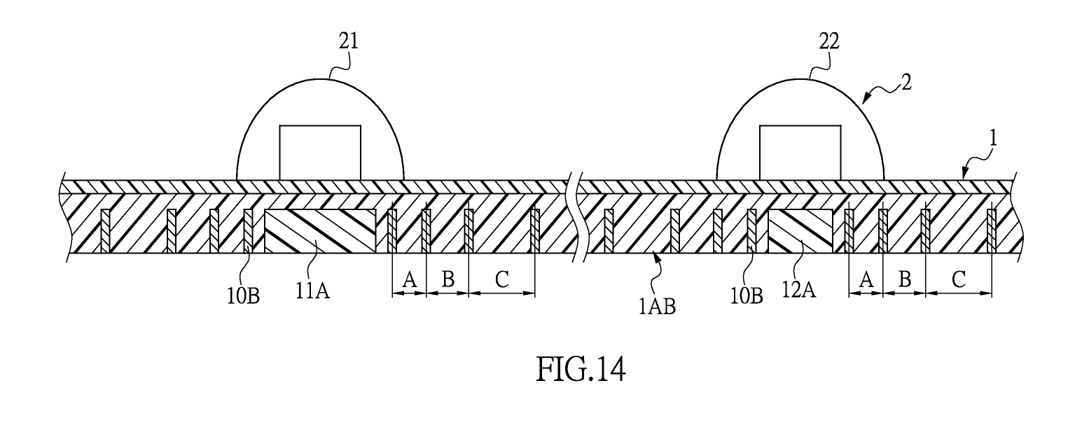

Referring to FIG. 14, the sixth embodiment of the present disclosure provides a light-emitting structure. From comparison of FIG. 14 to FIG. 11, it can be seen that the greatest difference between the sixth and third embodiment of the present disclosure lies in that: in the sixth embodiment, the thermal conducting unit 1A of the third embodiment and the thermal spreading unit 1B are integrated to form a compound thermal dissipating layer 1AB. Specifically, each of the first heat dissipating structures 11A positioned in the compound heat dissipating layer 1AB is closely surrounded by heat dissipating channels 10B which are separate and have similar dimensions, and the gap distances (A, B, C) between two neighboring heat dissipating channels 10B increase in the direction from the center to the periphery of the corresponding first heat dissipating structure 11A. Likewise, each of the second heat dissipating structures 12A positioned in the compound heat dissipating layer 1AB is closely surrounded by heat dissipating channels 10B which are separate and have similar dimensions, and the gap distances (A, B, C) between two neighboring heat dissipating channels 10B increase in the direction from the center to the periphery of the corresponding second heat dissipating structure 12A. By this method, the present embodiment can reduce the temperature difference between the first and second LED units (21, 22) of different color temperatures.

### Seventh Embodiment

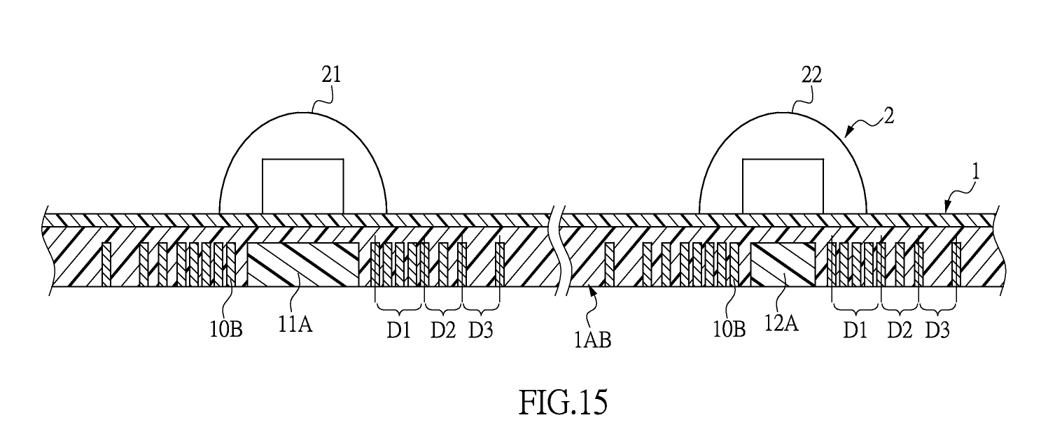

Referring to FIG. 15, the seventh embodiment of the present disclosure provides a light-emitting structure. From comparison of FIG. 15 to FIG. 12, it can be seen that the greatest difference between the seventh and fourth embodiment of the present disclosure lies in that: in the seventh embodiment, the thermal conducting unit 1A of the fourth embodiment and the thermal spreading unit 1B are integrated to form a compound thermal dissipating layer 1AB. Specifically, each of the first heat dissipating structures 11A positioned in the compound heat dissipating layer 1AB is closely surrounded by heat dissipating channels 10B which are separate and have similar dimensions, and the volumetric densities (D1, D2, D3) of the heat dissipating channels 10B decrease in the direction from the center to the periphery of the corresponding first heat dissipating structure 11A. Likewise, each of the second heat dissipating structures 12A positioned in the compound heat dissipating layer 1AB is closely surrounded by heat dissipating channels 10B which are separate and have similar dimensions, and the volumetric densities (D1, D2, D3) of the heat dissipating channels 10B decrease in the direction from the center to the periphery of the corresponding second heat dissipating structure 12A. By this method, the present embodiment can reduce the temperature difference between the first and second LED units (21, 22) of different color temperatures.

### Eighth Embodiment

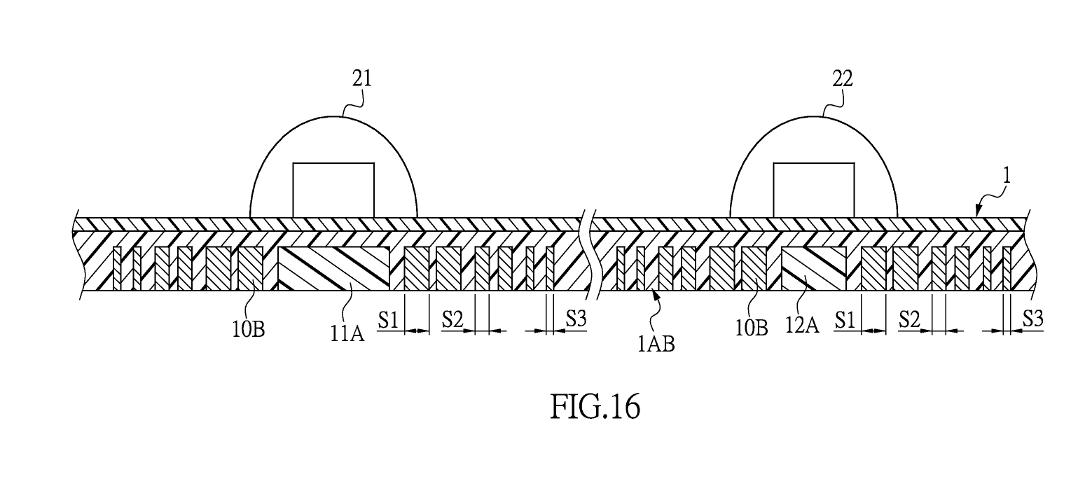

Referring to FIG. 16, the eighth embodiment of the present disclosure provides a light-emitting structure. From comparison of FIG. 16 to FIG. 13, it can be seen that the greatest difference between the eighth and fifth embodiment of the present disclosure lies in that: in the seventh embodiment, the thermal conducting unit 1A of the fourth embodiment and the thermal spreading unit 1B are integrated to form a compound thermal dissipating layer 1AB. Specifically, each of the first heat dissipating structures 11A positioned in the compound heat dissipating layer 1AB is closely surrounded by heat dissipating channels 10B which are separate, and the dimensions (S1, S2, S3) of the heat dissipating channels 10B decrease in the direction from the center to the periphery of the corresponding first heat dissipating structure 11A. Likewise, each of the second heat dissipating structures 12A positioned in the compound heat dissipating layer 1AB is closely surrounded by heat dissipating channels 10B which are separate, and the dimensions (S1, S2, S3) of the heat dissipating channels 10B decrease in the direction from the center to the periphery of the corresponding second heat dissipating structure 12A. By this method, the present embodiment can reduce the temperature difference between the first and second LED units (21, 22) of different color temperatures.

### Ninth Embodiment

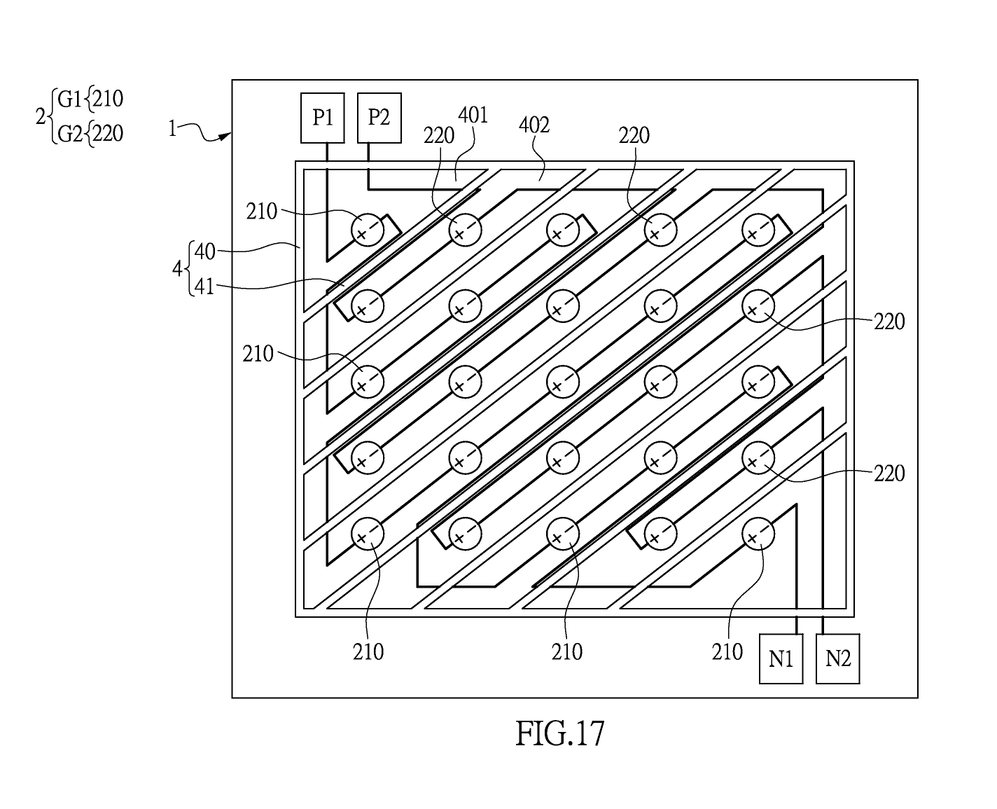

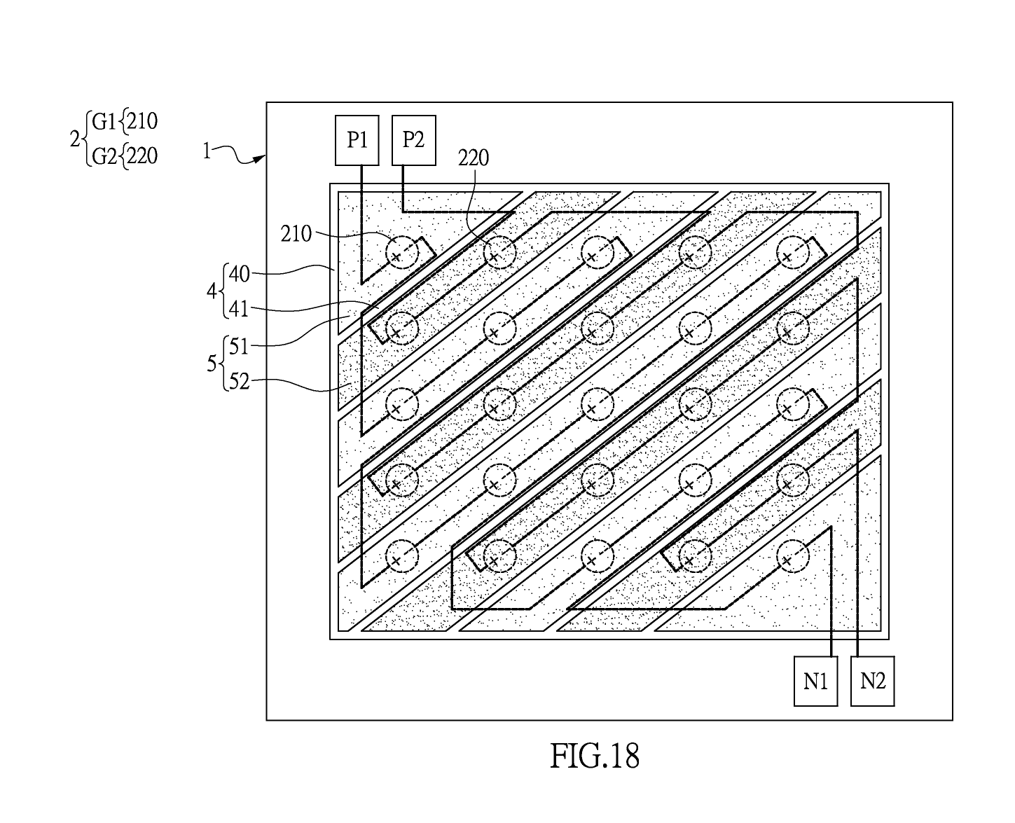

Referring to FIG. 17 and FIG. 18, the ninth embodiment of the present disclosure provides a light-emitting structure. During production, firstly a frame gel body 4 is formed on the substrate 1 (such as a circuit board) having a predetermined circuit (as shown in FIG. 17). Then, first fluorescent gels 51 and second fluorescent gels 52 which are different respectively fill corresponding first restricting spaces 401 and corresponding second restricting spaces 402 (as shown in FIG. 18).

Specifically, as shown in FIG. 17, the frame gel body 4 includes an outer frame portion 40 arranged on the substrate 1 and surrounding the light-emitting unit 2, and a plurality of connecting portions 41 arranged on the substrate 1 and surrounded by the outer frame portion 40. Two opposite ends of each of the connecting portions 41 are connected to an inner face of the outer frame portion 40. Each of the connecting portions 41 is arranged between a first light-emitting group G1 and a neighboring second light-emitting group G2, to form a plurality of first restricting spaces 401 for accommodating the first light-emitting groups G1 and a plurality of second restricting spaces 402 for accommodating the second light-emitting groups G2. The first restricting spaces 401 and the second restricting spaces 402 are alternately arranged. Moreover, as shown in FIG. 18, a package gel body 5 includes a plurality of first fluorescent gels 51 filled in the plurality of first restricting spaces 401 for covering the first light-emitting groups G1, and a plurality of second fluorescent gels 52 filled in the plurality of second restricting spaces 402 for covering the second light-emitting groups G2, such that the first fluorescent gels 51 and the second fluorescent gels 52 are alternately arranged.

In practice, the light produced by the first LED chips 210 (bare chips which have not been packaged) of the first light-emitting groups G1 can pass through the first fluorescent gels 51 to produce a warm white light, and the light produced by the second LED chips 220 (bare chips which have not been packaged; the two bare chips of the present embodiment have be of same wavelength range) of the second light-emitting groups G2 can pass through the second fluorescent gels 52 to produce a cold white light. The ninth embodiment of the present disclosure achieves preferred light mixing effect through the design of “alternate arrangement of first light-emitting groups G1 formed by corresponding first fluorescent gels 51 and second light-emitting groups G2 formed by corresponding second fluorescent gels 52.”

### Tenth Embodiment

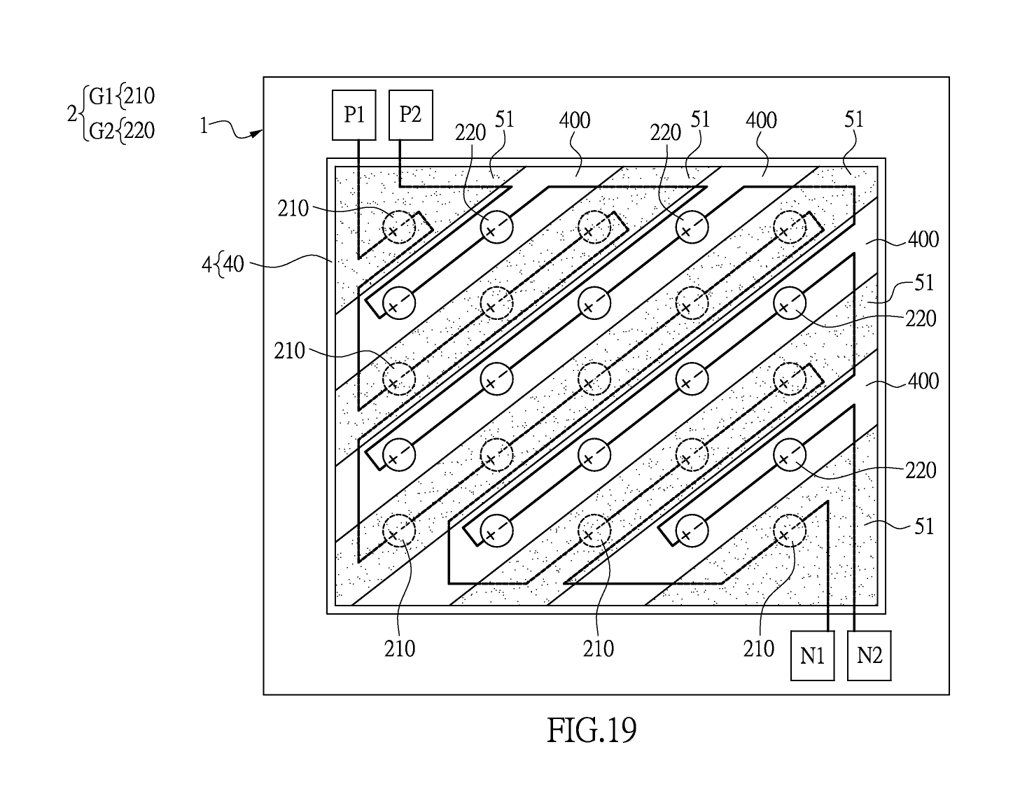

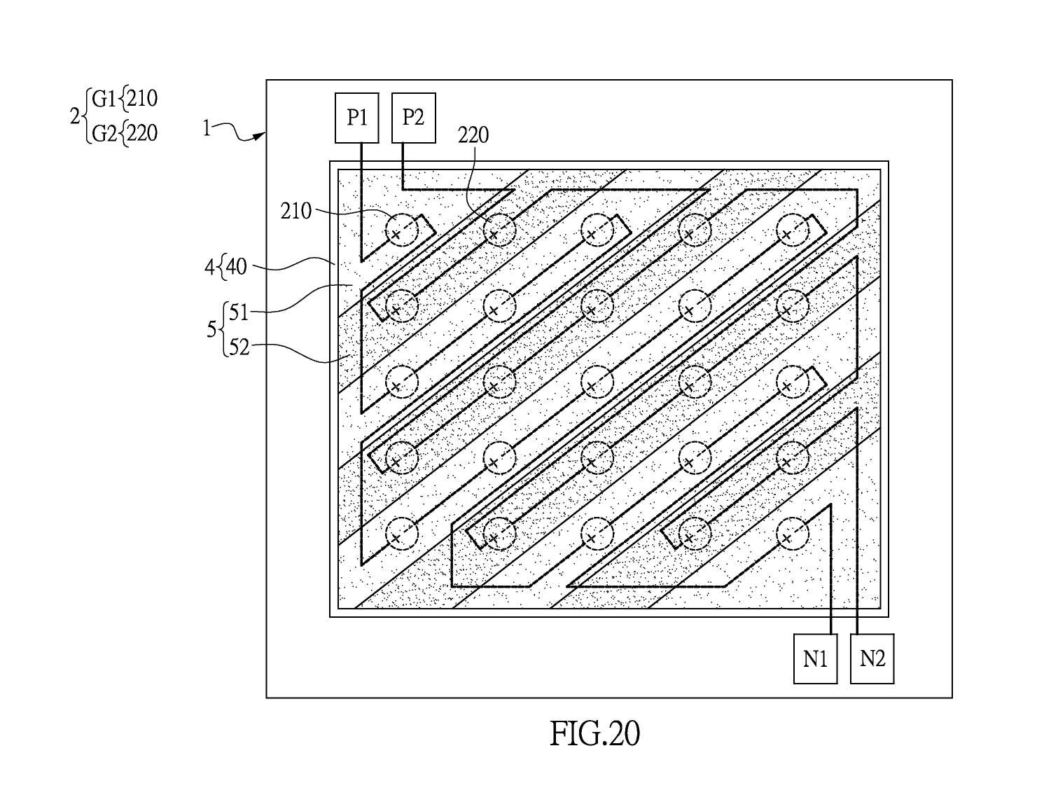

Referring to FIG. 19 and FIG. 20, the tenth embodiment of the present disclosure provides a light-emitting structure. During production, firstly a frame gel body 4 is formed on the substrate 1 (as shown in FIG. 19). Then first fluorescent gels 51 having high thixotropic coefficient respectively cover the first light-emitting groups G1 to form a plurality of restricting spaces 400 for accommodating second light-emitting groups G2 (as shown in FIG. 19). Finally, second fluorescent gels 52 having a typical thixotropic coefficient are filled in the restricting spaces 400 to respectively cover the second light-emitting groups G2 (as shown in FIG. 20).

Specifically, as shown in FIG. 19 and FIG. 20, the frame gel body 4 includes an outer frame portion arranged on the substrate 1 and surrounding the light-emitting unit 2 and the package gel body 5. The package gel body 5 includes a plurality of first fluorescent gels 51 covering the plurality of first restricting spaces 401 for covering the first light-emitting groups G1, and a plurality of second fluorescent gels 52 covering the plurality of second restricting spaces 402 for covering the second light-emitting groups G2, such that the first fluorescent gels 51 and the second fluorescent gels 52 are alternately arranged. In practice, the light produced by the first LED chips 210 of the first light-emitting groups G1 can pass through the first fluorescent gels 51 to produce a relatively low first color temperature, and the light produced by the second LED chips 220 of the second light-emitting groups G2 can pass through the second fluorescent gels 52 to produce a relative high second color temperature.

In summary of the above, the advantage of the present disclosure lies in that the light-emitting structure provided by the embodiments of the present disclosure can increase the light mixing effect between the plurality of first light-emitting groups G1 and the plurality of second light-emitting groups G2 of different color temperatures through the designs of “the one or the plurality of first LED chips 210 of a first light-emitting group G1 is disposed on the same first chip-mounting line 1100 of the corresponding first chip-mounting area 110, and the one or the plurality of second LED chips 220 of a second light-emitting group G1 is disposed on the same second chip-mounting line 1200 of the corresponding first chip-mounting area 120” and “the first chip-mounting areas 110 and the second chip-mounting areas 120 are alternately arranged, such that the first light-emitting groups G1 and the second light-emitting groups G2 are alternately arranged.”

It is worth mentioning that color tunable LEDs device by a combination of warm white (2700K) and cool white (5000K) multi CSP (Chip Scale Package) LEDs. It shows ultra-uniform mixing color by homogeneous alignment, and also smooth tuning by varying their relative driving current. It is revolutionary, energy efficient and compact new variable color light source, combining the long lifetime and reliability advantages. It provides a total design freedom and creating a new opportunities for application of intelligent lighting.

The descriptions illustrated supra set forth simply the preferred embodiments of the present disclosure; however, the characteristics of the present disclosure are by no means restricted thereto. All changes, alternations, or modifications conveniently considered by those skilled in the art are deemed to be encompassed within the scope of the present disclosure delineated by the following claims.

What is claimed is:

1. A light-emitting structure comprising:
a substrate having at least one meandering first conductive track and at least one meandering second conductive track, wherein each of the first conductive tracks has a plurality of first chip-mounting areas, each of the first chip-mounting areas has at least two first chip-mounting lines, each of the second conductive tracks has a plurality of second chip-mounting areas, each of the second chip-mounting areas has at least two second chip-mounting lines; and
a light-emitting unit including a plurality of first light-emitting groups and a plurality of second light-emitting groups, wherein each of the first light-emitting groups includes one or a plurality of first LED chips, and each of the second light-emitting groups includes one or a plurality of second LED chips;
wherein the one or the plurality of first LED chips of each of the first light-emitting groups is disposed on the same first chip-mounting line of the corresponding first chip-mounting area, and the one or the plurality of second LED chips of each of the second light-emitting groups is disposed on the same second chip-mounting line of the corresponding second chip-mounting area;
wherein the first chip-mounting areas and the second chip-mounting areas are alternately arranged, and the first light-emitting groups and the second light-emitting groups are alternately arranged.

2. The light-emitting structure according to claim 1, wherein the first chip-mounting lines with the first LED chips disposed thereon and the second chip-mounting lines with the second LED chips disposed thereon are parallel, any neighboring first light-emitting group and second light-emitting group are parallel and have the same gap distance therebetween, and the first LED chips and the second LED chips are alternately arranged to form an array.

3. The light-emitting structure according to claim 1, wherein a positive bonding pad of each of the first LED chips and a positive bonding pad of each of the second LED chips face toward a same first predetermined direction with respect to the substrate, a negative bonding pad of each of the first LED chips and a negative bonding pad of each of the second LED chips face toward a same second predetermined direction with respect to the substrate, the orientation with respect to the substrate of the positive and negative bonding pads of each of the first LED chips is the same as the orientation with respect to the substrate of the positive and negative bonding pads of each of the second LED chips.

4. The light-emitting structure according to claim 1, wherein the upper surface of the substrate has an accommodating groove for accommodating an optical sensor, and the inner surface of the accommodating groove has a light-absorbing coating.

5. The light-emitting structure according to claim 1, wherein the substrate further includes a plurality of first heat dissipating structures disposed under the plurality of the first LED chips and a plurality of second heat dissipating structures disposed under the plurality of second LED chips, and the color temperature produced by a first LED unit formed from packaging the first LED chips is smaller than the color temperature produced by a second LED unit formed from packaging the second LED chips.

6. The light-emitting structure according to claim 5, wherein when the first heat dissipating structures and the second heat dissipating structures use material of the same heat dissipating abilities, the dimensions of the first heat dissipating structures are greater than the dimensions of the second heat dissipating structures, and when the dimensions of the first heat dissipating structures and the dimensions of the second heat dissipating structures are substantially the same, the heat dissipating ability of the material used by the first heat dissipating structures is greater than the heat dissipating ability of the material used by the second heat dissipating structures.

7. The light-emitting structure according to claim 5, wherein the dimensions of the first heat dissipating structures and the dimensions of the second heat dissipating structures decrease in the direction from the center to the periphery of the substrate.

8. The light-emitting structure according to claim 7, wherein the ratio of the decreasing dimensions of the first heat dissipating structures in the direction from the center to the periphery of the substrate is substantially the same as the ratio of the decreasing dimensions of the second heat dissipating structures in the direction from the center to the periphery of the substrate.

9. The light-emitting structure according to claim 5, wherein the substrate further includes a thermal conducting unit having a plurality of first and second heat dissipating structures and a thermal spreading unit positioned under the thermal conducting unit.

10. The light-emitting structure according to claim 6, wherein the ratio of the heat transfer rates of the first dissipating structures and the second heat dissipating structures is 1:0.86-0.95.

11. The light-emitting structure according to claim 1, wherein the upper surface of the substrate has an accommodating groove for accommodating an electronic component, the inner portion of the substrate further includes a plurality of thermal conducting units positioned under the first and second LED chips and a thermal resistant structure disposed between the electronic component and the light-emitting unit, wherein the thermal conductivities of the substrate, the thermal resistant structure and the thermal conducting unit are respectively k1, k2 and k3, and k3>k1>k2.

12. The light-emitting structure according to claim 9, wherein the interior portion of the thermal spreading unit includes a plurality of separate heat dissipating channels, and the plurality of heat dissipating channels uses one of a first, a second and a third structures, wherein the first structure is that the dimensions of the heat dissipating channels are the same, and the gap distance between two neighboring heat dissipating channels decrease from the center to the periphery of the thermal conducting unit, wherein the second structure is that the dimensions of the heat dissipating channels are the same, and the volumetric densities of the heat dissipating channels occupying the thermal spreading unit decrease from the center to the periphery of the thermal conducting unit, wherein the third structure is that the dimensions of the heat dissipating channels decrease from the center to the periphery of the thermal conducting unit.

13. The light-emitting structure according to claim 6, wherein each of the first and second heat dissipating structures is closely surrounded by separate heat dissipating channels, and the plurality of heat dissipating channels uses one of a first, a second and a third structures, wherein the first structure is that the dimensions of the heat dissipating channels of each of the first and second heat dissipating structures are the same, and the gap distance between two neighboring heat dissipating channels decrease from the center to the periphery of the corresponding first or second heat dissipating structure, wherein that second structure is that the dimensions of the heat dissipating channels of each of the first and second heat dissipating structures are the same, and the volumetric densities of the heat dissipating channels decrease from the center to the periphery of the corresponding first or second heat dissipating structure, wherein the third structure is that the dimensions of the heat dissipating channels decrease from the center to the periphery of the corresponding first or second heat dissipating structure.

14. The light-emitting structure according to claim 1, further comprising a frame gel body and a package gel body, wherein the frame gel body includes an outer frame portion arranged on the substrate and surrounding the light-emitting unit, and a plurality of connecting portions arranged on the substrate and surrounded by the outer frame portion, two opposite ends of each of the connecting portions are connected to an inner face of the outer frame portion, each of the connecting portions is arranged between a first light-emitting group and a neighboring second light-emitting group to form a plurality of first restricting spaces for accommodating the first light-emitting groups and a plurality of second restricting spaces for accommodating the second light-emitting groups, wherein the package gel body includes first fluorescent gels respectively filled in the first restricting spaces for respectively covering the first light-emitting groups and second fluorescent gels respectively filled in the second restricting spaces for respectively covering the second light-emitting groups, and the first fluorescent gels and the second fluorescent gels are alternately arranged.

15. The light-emitting structure according to claim 1, further comprising a frame gel body and a package gel body, wherein the frame gel body includes an outer frame portion arranged on the substrate and surrounding the light-emitting unit, the package gel body includes first fluorescent gels respectively covering the first light-emitting groups and second fluorescent gels respectively covering the second light-emitting groups, wherein the first fluorescent gels and the second fluorescent gels are alternately arranged, and the first fluorescent gels and the second fluorescent gels have different thixotropic coefficients.

16. The light-emitting structure according to claim 1, wherein the first LED chips and the second LED chips present a circular or a substantially circular arrangement distribution, and the circular track defined by the four outermost first LED chips and the circular track defined by the four outermost second Led chips substantially or completely overlap to form a single circular track.

17. The light-emitting structure according to claim 1, wherein the substrate an additional meandering first conductive track, and additional meandering second conductive track, a via hole passing through the substrate, a second via hole passing through the substrate, a first backside circuit disposed at the backside of the substrate, a second backside circuit disposed at the backside of the substrate, one end of the at least one first conductive track and one end of the at least one second conductive track are respectively connected to a first positive bonding pad and a second positive bonding pad, and one end of the additional first conductive track and one end of the additional second conductive track are respectively connected to a first negative bonding pad and a second negative bonding pad, wherein the other end of the additional first conductive track is connected to the first positive bonding pad sequentially through the first via hole and the first backside circuit, the other end of the additional second conductive track is directly connected to the second positive bonding pad, the other end of the at least one first conductive track is directly connected to the first negative bonding pad, and the other end of the at least one second conductive track is connected to the second negative bonding pad sequentially through the second via hole and the second backside circuit.
